(19) United States
(12) Patent Application Publication
(10) Pub. No.: US 2024/0258391 A1
(43) Pub. Date: Aug. 1, 2024

(54) SEMICONDUCTOR DEVICE AND METHOD OF MANUFACTURING SEMICONDUCTOR DEVICE

(71) Applicant: SK hynix Inc., Icheon-si Gyeonggi-do (KR)

(72) Inventors: Rho Gyu KWAK, Icheon-si Gyeonggi-do (KR); In Su PARK, Icheon-si Gyeonggi-do (KR); Jung Shik JANG, Icheon-si Gyeonggi-do (KR); Jung Dal CHOI, Icheon-si Gyeonggi-do (KR); Seok Min CHOI, Icheon-si Gyeonggi-do (KR); Won Geun CHOI, Icheon-si Gyeonggi-do (KR)

(73) Assignee: SK hynix Inc., Icheon-si Gyeonggi-do (KR)

(21) Appl. No.: 18/323,323

(22) Filed: May 24, 2023

(30) Foreign Application Priority Data
Jan. 26, 2023 (KR) 10-2023-0010283

(51) Int. Cl. H01L 29/423; H01L 23/528; H01L 23/532

(52) U.S. Cl. CPC H01L 29/42356; H01L 23/5283; H01L 23/53204; H01L 23/5329

(57) ABSTRACT

A semiconductor device according to an embodiment of the present disclosure includes a first cell area and a second cell area adjacent to each other in a first direction, a support disposed between the first cell area and the second cell area, first gate lines stacked in the first cell area, first pads configured to extend from the first gate lines and configured to protrude upward along a first sidewall of the support, second gate lines stacked in the second cell area, second pads configured to extend from the second gate lines and configured to protrude upward along a second sidewall of the support, and first connection pads configured to extend in the first direction along a third sidewall of the support and configured to electrically connect the first pads with the second pads.

### CROSS-REFERENCE TO RELATED APPLICATION

This application claims priority under 35 U.S.C. §119(a) to Korean Patent Application No. 10-2023-0010283 filed on Jan. 26, 2023, in the Korean Intellectual Property Office, which is incorporated herein by reference in its entirety.

### BACKGROUND

### 1. Technical Field

Embodiments relate to a semiconductor device and a method of manufacturing a semiconductor device, and more particularly, to a method of manufacturing a semiconductor device, which can reduce the number of process steps.

### 2. Related Art

Recently, as an electronic device is reduced in size, has low power consumption and high performance, and is diversified, a semiconductor device capable of storing information is required for various electronic devices, such as computers and portable communication devices.

In order to reduce the size of the semiconductor device and increase the data storage capacity of the semiconductor device, the semiconductor device has been developed so that many memory cells can be integrated in the same area of the semiconductor device by reducing a metal line width in a two-dimensional (2-D) plane.

As the metal line width is reduced in the 2-D plane, there is a problem in that manufacturing equipment, investment costs, and a development period are exponentially increased. Accordingly, a method of manufacturing the semiconductor device using a three-dimensional (3-D) structure is researched and developed.

### SUMMARY

In an embodiment, a semiconductor device may include a first cell area and a second cell area adjacent to each other in a first direction, a support disposed between the first cell area and the second cell area, first gate lines stacked in the first cell area, first pads configured to extend from the first gate lines and configured to protrude upward along a first sidewall of the support, second gate lines stacked in the second cell area, second pads configured to extend from the second gate lines and configured to protrude upward along a second sidewall of the support, and first connection pads configured to extend in the first direction along a third sidewall of the support and configured to electrically connect the first pads with the second pads.

In an embodiment, a method of manufacturing a semiconductor device may include forming a support disposed between a first cell area and a second cell area that are adjacent to each other in a first direction, forming, on the support, a stack including first material layers and second material layers that are alternately stacked, and patterning the stack so that each of the first material layers comprises a first line part disposed in the first cell area, a first pad part configured to extend from the first line part and configured to protrude upward along a first sidewall of the support, a second line part disposed in the second cell area, a second pad part configured to extend from the second line part and configured to protrude upward along a second sidewall of the support, and a first connection part configured to extend in a first direction along a third sidewall of the support and configured to connect the first pad part with the second pad part.

### BRIEF DESCRIPTION OF THE DRAWINGS

FIGS. 1A, 2A, 3A, 4A, 5A, 6A, and 7A are cross-sectional views for describing a method of manufacturing a semiconductor device according to an embodiment of the present disclosure.

FIGS. 1B, 2B, 3B, 4B, 5B, 6B, and 7B are plan views for describing a method of manufacturing a semiconductor device according to an embodiment of the present disclosure.

FIG. 3C is a cross-sectional view for describing a method of manufacturing a semiconductor device according to another embodiment of the present disclosure.

FIGS. 8 to 10 are diagrams for describing a semiconductor device according to an embodiment of the present disclosure.

FIG. 11 is a diagram for describing a semiconductor device according to another embodiment of the present disclosure.

FIGS. 12, 13A, 13B, 13C, 14A, 14B, 14C, 15A, 15B, 15C, 16A, 16B, and 16C are diagrams for describing a method of manufacturing a semiconductor device according to another embodiment of the present disclosure.

FIGS. 17 to 20 are diagrams for describing a semiconductor device according to another embodiment of the present disclosure.

### DETAILED DESCRIPTION

Hereinafter, embodiments according to the technical spirit of the present disclosure are described with reference to the accompanying drawings.

Embodiments of the present disclosure provide a semiconductor device in which adjacent cell areas can be electrically connected.

Embodiments of the present disclosure provide a method of manufacturing a semiconductor device, which can reduce the number of process steps.

There is an effect in that the number of process steps can be reduced.

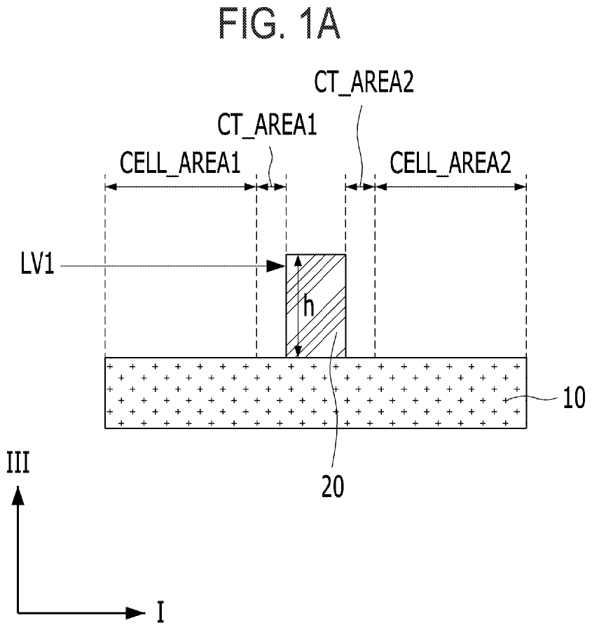

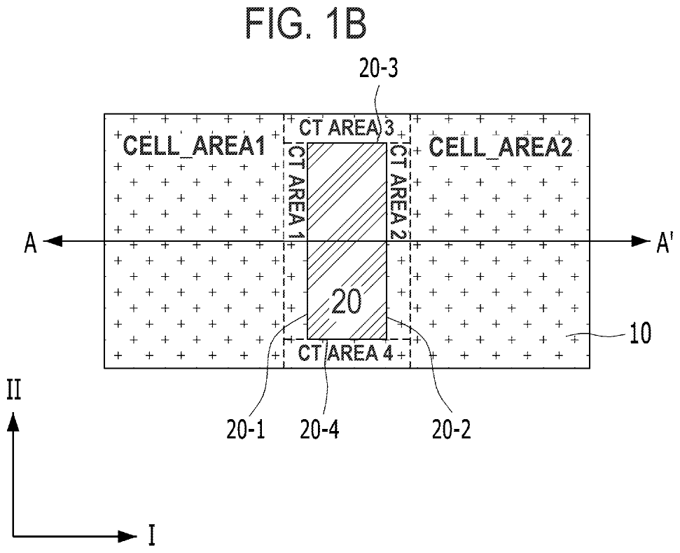

FIGS. 1A to 5A are cross-sectional views for describing a method of manufacturing a semiconductor device according to an embodiment of the present disclosure. In this case, FIGS. 1A to 5A may be cross-sectional views taken along line A-A′ in FIGS. 1B to 5B.

FIGS. 1B to 5B may be plan views according to a level 1 LV1 in FIGS. 1A to 5A.

Referring to FIGS. 1A and 1B, a support 20 may be formed. As an embodiment, the support 20 may be formed in a form that includes a first sidewall 20-1 and a second sidewall 20-2 that extend in a second direction II and a third sidewall 20-3 and a fourth sidewall 20-4 that extend in a first direction I. The support 20 may be formed over a substrate 10. For example, the support 20 may be formed to have a hexahedral form by forming a material layer on the substrate 10 and etching the material layer. Alternatively, the support 20 may be formed by patterning the substrate 10. The material layer may include silicon or polysilicon. In this case, the first to fourth sidewalls 20-1, 20-2, 20-3, and 20-4 of the support 20 may have a height h in a third direction III. The third direction III may be a direction that is orthogonal to a plane that has been defined by the first direction I and the second direction II.

The substrate 10 may include a first cell area CELL AREA1 and a second cell area CELL AREA2 that are adjacent to each other in the first direction I. The support 20 may be disposed on the substrate 10 between the first cell area CELL AREA1 and the second cell area CELL AREA2. In this case, the first cell area CELL AREA1 may be a location at which a first memory block will be formed, and the second cell area CELL AREA2 may be a location at which a second memory block will be formed. In a subsequent process, first gate lines may be stacked in the first cell area CELL AREA1, and second gate lines may be stacked in the second cell area CELL AREA2.

A first contact area CT AREA1, a second contact area CT AREA2, a third contact area CT AREA3, and a fourth contact area CT AREA4 may be disposed along the sidewalls 20-1, 20-2, 20-3, and 20-4 of the support 20.

The first contact area CT AREA1 may be disposed between the first cell area CELL AREA1 and the support 20 and may extend along the first sidewall 20-1 of the support 20. In a subsequent process, first pads may be formed in the first contact area CT AREA1. The first pads may extend from the first gate lines and may protrude upward along the first sidewall 20-1 of the support 20. First contacts may be connected to the first pads, respectively.

The second contact area CT AREA2 may be disposed between the second cell area CELL AREA2 and the support 20 and may extend along the second sidewall 20-2 of the support 20. In a subsequent process, second pads may be formed in the second contact area CT AREA2. The second pads may extend from the second gate lines and may protrude upward along the second sidewall 20-2 of the support 20. Second contacts may be connected to the second pads, respectively.

The third contact area CT AREA3 may be disposed between the first cell area CELL AREA1 and the second cell area CELL AREA2 and mayextend along the third sidewall 20-3 of the support 20. In a subsequent process, first connection pads that electrically connect the first pads with the second pads may be formed in the third contact area CT AREA3. The first connection pads may be connected to third contacts, respectively.

The fourth contact area CT AREA4 may be disposed between the first cell area CELL AREA1 and the second cell area CELL AREA2 and may extend along the fourth sidewall 20-4 of the support 20. In a subsequent process, second connection pads that electrically connect the first pads with the second pads may be formed in the fourth contact area CT AREA4. The second connection pads may be connected to fourth contacts, respectively.

In a subsequent process, a first connection area and a second connection area in which the first and second connection pads will be formed may be adjacent to each other in the third direction III. The support 20, the first contact area CT AREA1, and the second contact area CT AREA2 may be disposed between the first connection area and the second connection area.

The first gate lines, the first pads, the second gate lines, the second pads, the first connection pads, the second connection pads, the first contacts, the second contacts, the third contacts, and the fourth contacts will be described in detail later.

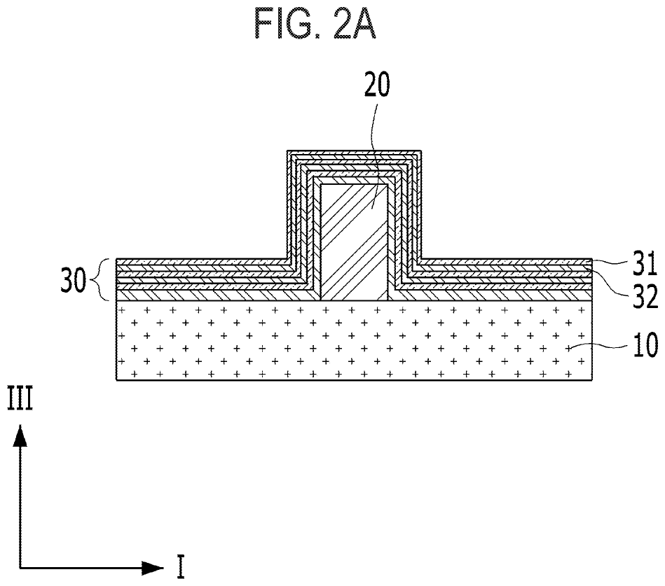

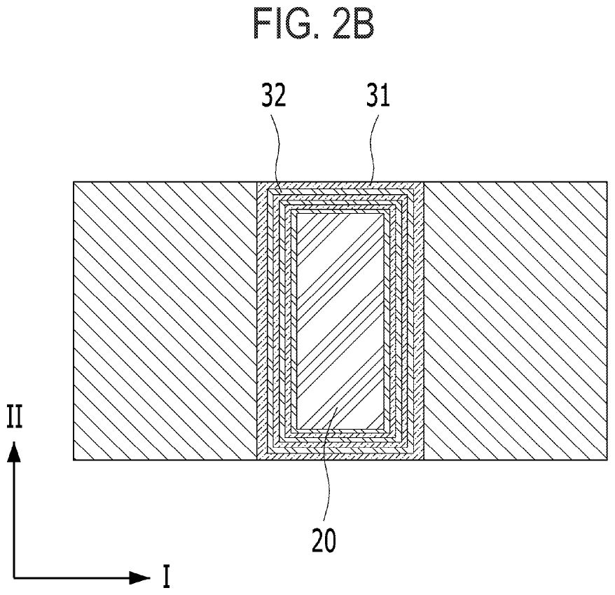

Referring to FIGS. 2A and 2B, a stack 30 may be formed. The stack 30 may be formed by alternately stacking first material layers 31 and second material layers 32 over the substrate 10 and along a profile of the support 20. The stack 30 may be formed along the upper surface of the substrate 10 and the upper surfaces of the first to fourth sidewalls 20-1, 20-2, 20-3, and 20-4 of the support 20. The first material layers 31 may include a material having a high etch selectivity with respect to the second material layers 32. The first material layer 31 may be for forming gate lines, such as a word line, a selection line, and a bit line. The second material layer 32 may be for mutually insulating stacked gate lines. For example, the first material layer 31 may include a sacrificial material, such as a nitride. The second material layer 32 may include an insulating material, such as an oxide. As another example, the first material layers 31 may include a conductive material, such as polysilicon, tungsten, or molybdenum. The second material layers 32 may include an insulating material, such as an oxide.

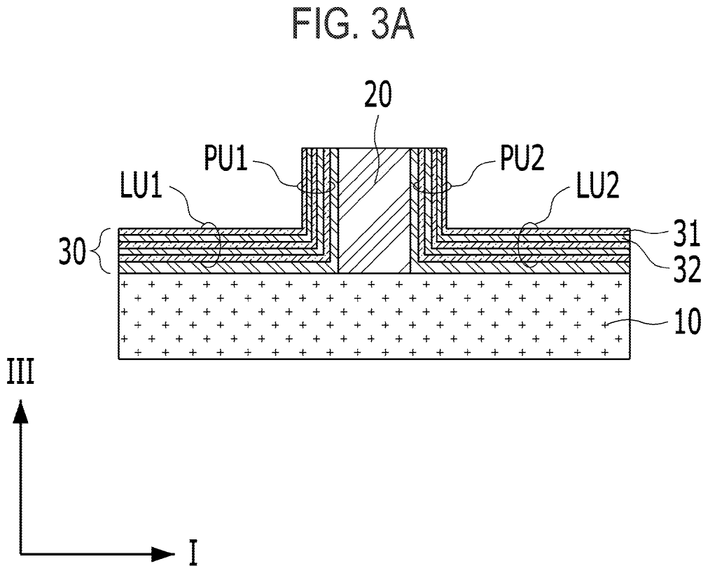

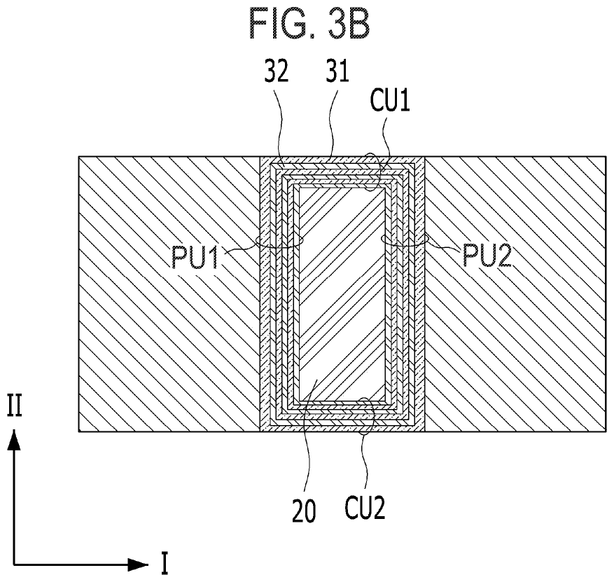

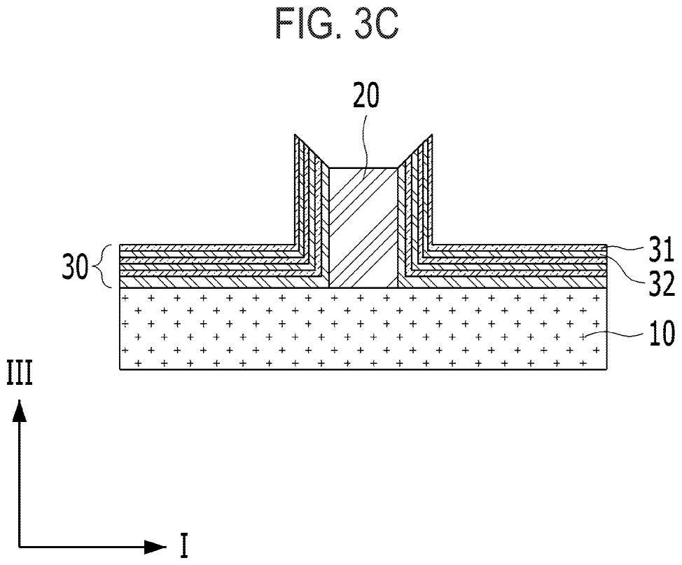

Referring to FIGS. 3A and 3B, a stack 30 may be etched or planarized until the support 20 is exposed. The planarization process may be performed by using a chemical mechanical polishing (CMP) process. Furthermore, further referring to FIG. 3C, after a part of the stack 30 formed over the support 20 is etched, the stack 30 may be etched or planarized up to the upper surface of the support 20 as illustrated in FIG. 3A.

The stack 30 may be patterned so that each of the first material layers 31 includes a first line part LU1 that is disposed in the first cell area CELL AREA1 and a first pad part PU1 that extends from the first line part LU1 and that protrudes upward along the sidewall of the support 20 and each of the second material layers 32 includes a second line part LU2 that is disposed in the second cell area CELL AREA2, a second pad part PU2 that extends from the second line part LU2 and that protrudes upward along the sidewall of the support 20, and a first connection part CU1 that extends in the first direction along the sidewall of the support 20 and that connects the first pad part PU1 with the second pad part PU2. Furthermore, when the stack 30 is patterned, a second connection part CU2 that extends in the first direction I along the sidewall of the support 20 and that connects the first pad part PU1 with the second pad part PU2 may be additionally formed.

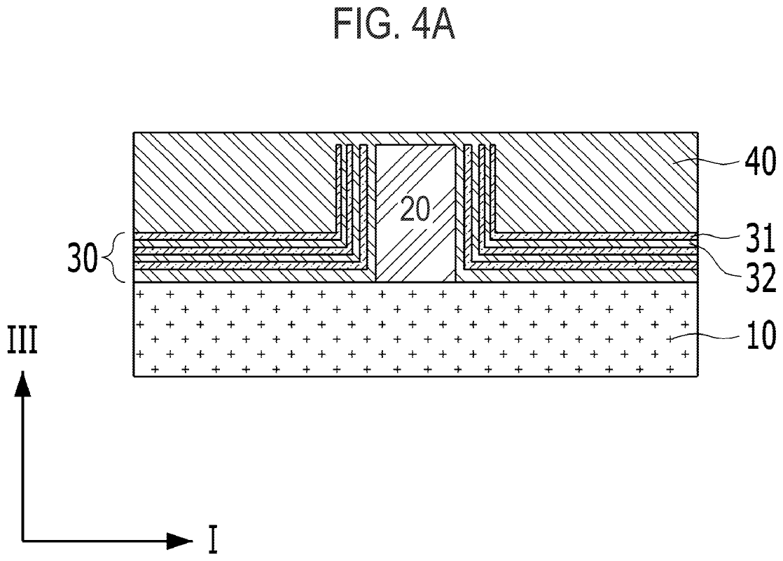

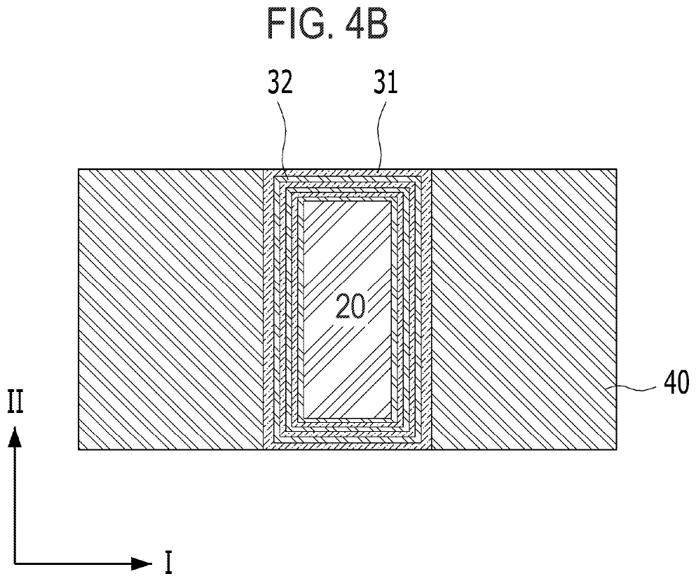

Referring to FIGS. 4A and 4B, an insulating layer 40 may be formed. The insulating layer 40 may be formed along the upper surface of the stack 30 and along a profile of the stack 30 and the support 20. FIG. 4A may be a drawing for describing a method of manufacturing a semiconductor device after the insulating layer 40 is formed and a planarization process is performed. The insulating layer 40 may include an oxide.

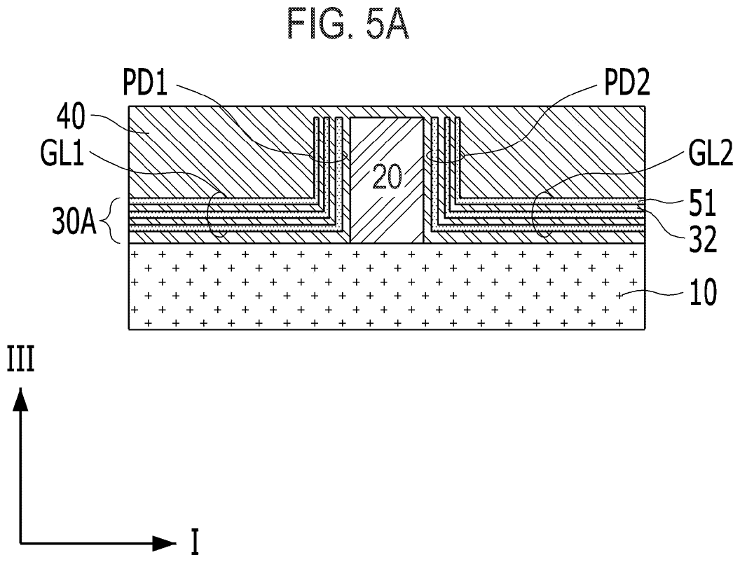

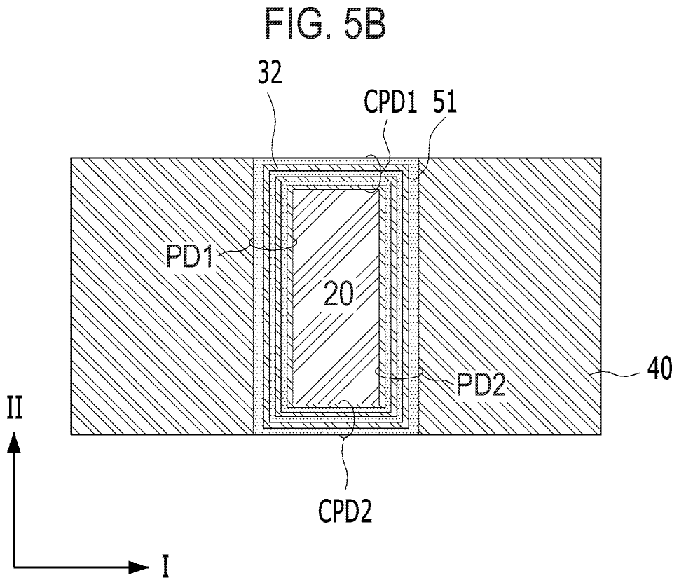

Referring to FIGS. 5A and 5B, conductive layers 51 may be formed. The first material layers 31 may be substituted with the conductive layers 51. As an embodiment, after a slit is formed within the stack 30, the first material layers 31 may be selectively etched through the slit, and the conductive layers 51 may be formed within an etched space. In this case, the conductive layer 51 may be a conductive material including metal, such as tungsten (W) or molybdenum (MO). Accordingly, a gate structure 30A including the conductive layers 51 and the second material layers 32 that are alternately stacked may be formed. The slit may be an opening that is formed between the memory block and the memory block. A method of forming the conductive layer 51 by using the slit is described later. For reference, if the first material layers 31 include a conductive material, a process of substituting the first material layers 31 with the conductive layers 51 may be omitted or a silicidation process may be performed.

The conductive layers 51 may include first gate lines GL1, second gate lines GL2, first pads PD1, second pads PD2, first connection pads CPD1, and second connection pads CPD2. The first gate lines GL1 may be stacked in the first cell area CELL AREA1. The first gate lines GL1 may extend in the first direction I. The first pads PD1 may extend from the first gate lines GL1 and may protrude upward along the first sidewall 20-1 of the support 20. The second gate lines GL2 may be stacked in the second cell area CELL AREA2. The second gate lines GL2 may extend in the first direction I. The second pads PD1 may extend from the second gate lines GL2 and may protrude upward along the second sidewall 20-2 of the support 20. The first connection pads CPD1 may be formed to extend in the first direction I along the third sidewall 20-3 of the support 20 and may electrically connect the first pads PD1 with the second pads PD2. The second connection pads CPD2 may be formed to extend in the first direction I along the fourth sidewall 20-4 of the support 20 and may electrically connect the first pads PD1 with the second pads PD2.

The first and second gate lines GL1 and GL2 may include a word line, a selection line, and a bit line. The first pads PD1, the second pads PD2, the first connection pads CPD1, and the second connection pads CPD2 may electrically connect the first and second gate lines GL1 and GL2 with a peripheral circuit (e.g., a row decoder).

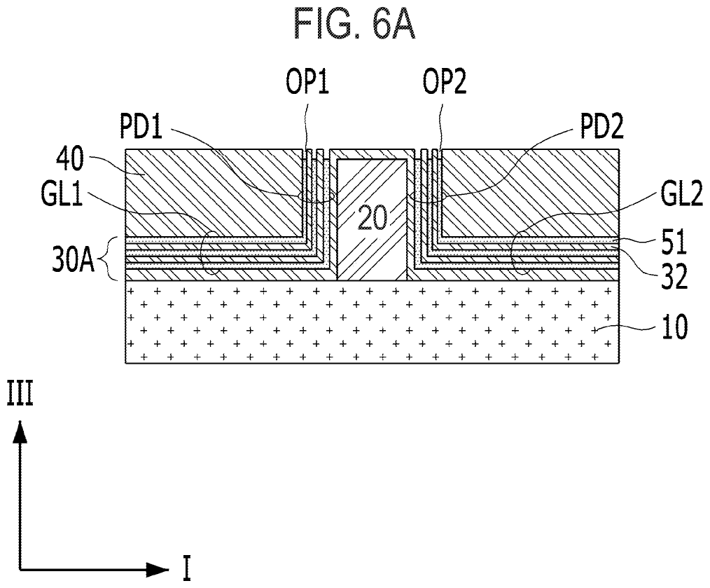

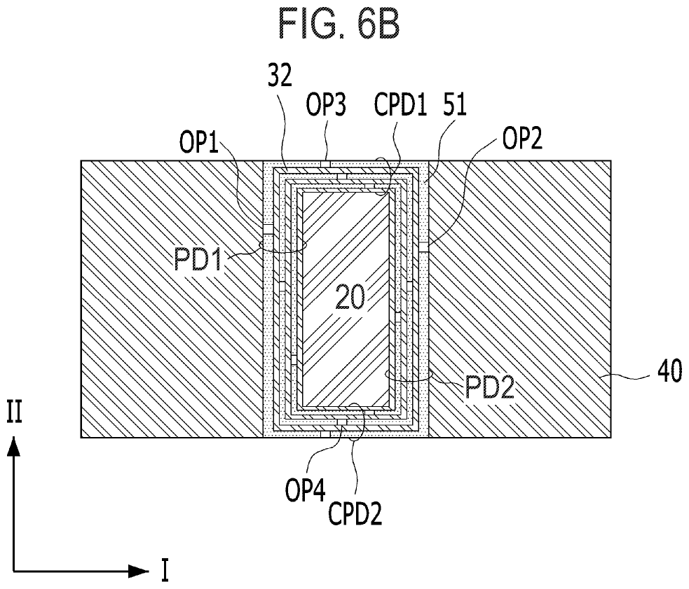

Referring to FIGS. 6A and 6B, openings OP1, OP2, OP3, and OP4 may be formed within the insulating layer 40. The openings OP1, OP2, OP3, and OP4 may be formed by etching the insulating layer 40. The openings OP1, OP2, OP3, and OP4 may include at least one of first openings OP1, second openings OP2, third openings OP3, and fourth openings OP4. The first openings OP1 may expose the first pads PD1. The second openings OP2 may expose the second pads PD2. The third openings OP3 may expose the first connection pads CPD1. The fourth openings OP4 may expose the second connection pads CPD2.

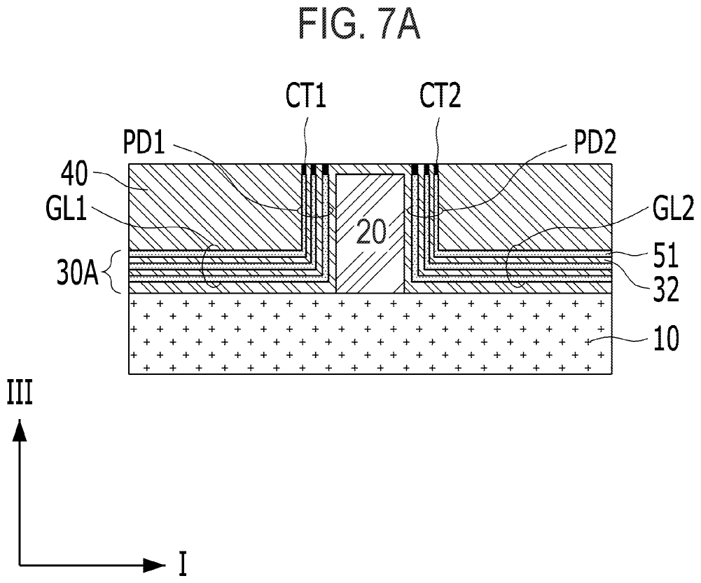

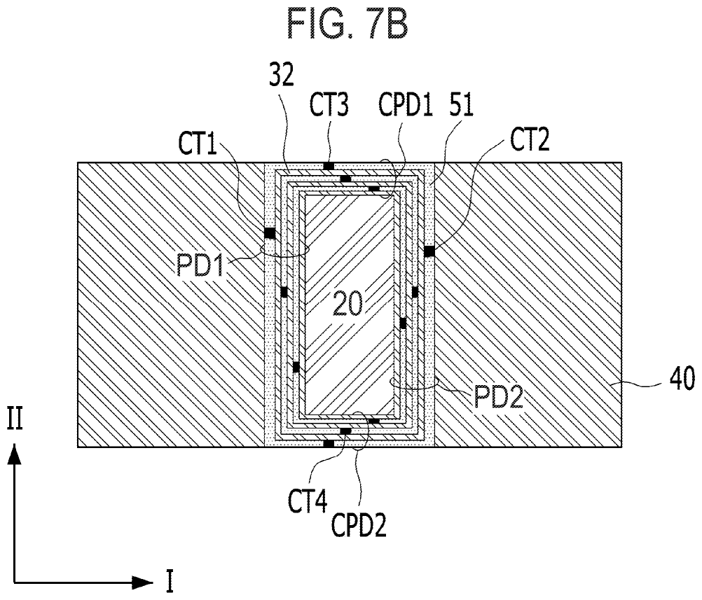

Referring to FIGS. 7A and 7B, contacts CT1, CT2, CT3, and CT4 may be formed. The contacts CT1, CT2, CT3, and CT4 may be formed by forming a conductive layer within the openings OP1, OP2, OP3, and OP4. The contacts CT1 to CT4 may be formed over the first pad PD1, the second pad PD2, the first connection pad CPD1, and the second connection pad CDP2. The contacts CT1, CT2, CT3, and CT4 may include at least one of first contacts CT1, second contacts CT2, third contacts CT3, and fourth contacts CT4. The first contacts CT1 may be formed by forming the conductive layer within the first openings OP1. The second contacts CT2 may be formed by forming the conductive layer within the second openings OP2. The third contacts CT3 may be formed by forming the conductive layer within the third openings OP3. The fourth contacts CT4 may be formed by forming the conductive layer within the fourth openings OP4. The first to fourth contacts CT1, CT2, CT3, and CT4 may be electrically connected to a peripheral circuit (e.g., a row decoder X_dec).

According to the aforementioned manufacturing method, the first pads PD1 and the second pads PD2 may be formed by using the support 20. Accordingly, although the stack 30 is not patterned in a step form, the first pads PD1 and the second pads PD2 may be formed. Furthermore, the first connection pads CPD1 and the second connection pads CPD2 may be formed by using the third sidewall 20-3 and fourth sidewall 20-4 of the support 20. Accordingly, the first pads PD1 and the second pads PD2 may be connected by the first and second connection pads CPD1 and CPD2. The first cell area CELL AREA1 and the second cell area CELL AREA2 may share a peripheral circuit, for example, a decoder.

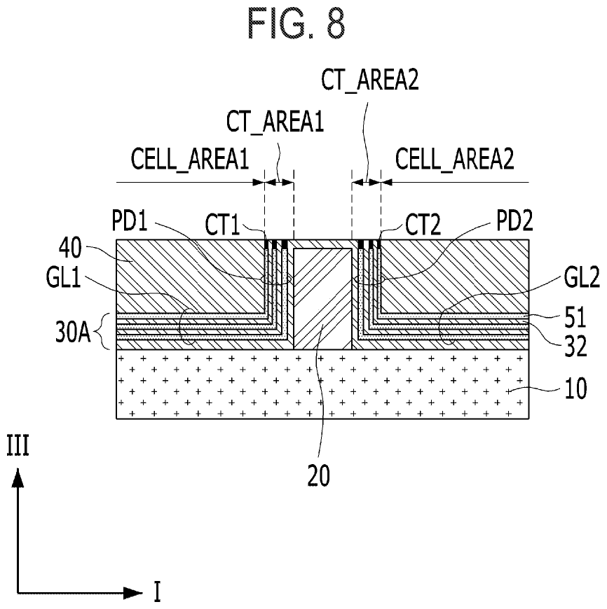

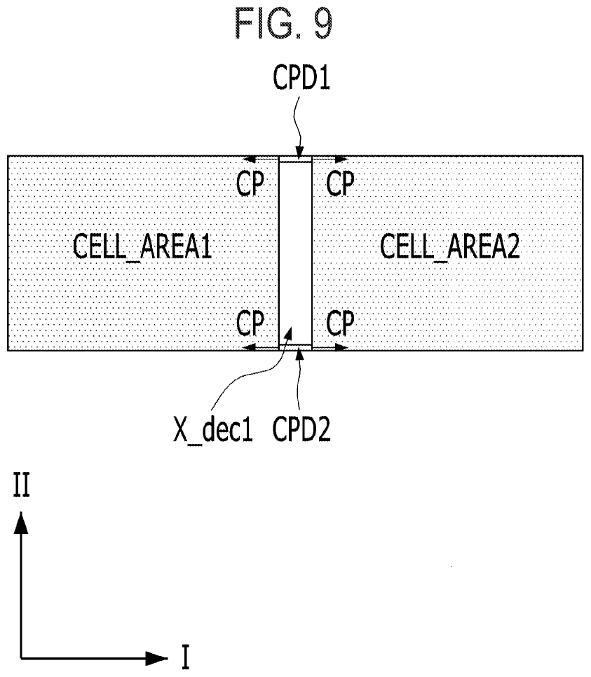

FIGS. 8 and 9 are diagrams for describing a semiconductor device according to an embodiment of the present disclosure. In this case, FIG. 9 may be a plan view of FIG. 8.

Referring to FIG. 8, the first contacts CT1 may be disposed in the first contact area CT AREA1, and the second contacts CT2 may be disposed in the second contact area CT AREA2. The first cell area CELL AREA1 may be an area in which first memory cells have been stacked. As an embodiment, first memory strings may be disposed in the first cell area CELL AREA1. The second cell area CELL AREA2 may be an area in which second memory cells have been stacked. As an embodiment, second memory strings may be disposed in the second cell area CELL AREA2.

The first gate lines GL1 may be stacked in the first cell area CELL AREA1. The first gate lines GL1 may extend in the first direction I. The first gate lines GL1 may include a word line, a selection line, and a bit line and may be electrically connected to the first memory strings.

The second gate lines GL2 may be stacked in the second cell area CELL AREA2. The second gate lines GL2 may extend in the first direction I. The second gate lines GL2 may include word lines, selection lines, and bit lines and may be electrically connected to the second memory strings.

Furthermore, the first pads PD1 and the first contacts CT1 may be disposed in the first contact area CT AREA1. The first pads PD1 may extend from the first gate lines GL1 and may protrude upward along the sidewall of the support 20. The first pads PD1 and the first contacts CT1 may be connected, respectively. The second pads PD2 may extend from the second gate lines GL2 and may protrude upward along the sidewall of the support 20. The second pads PD2 and the second contacts CT2 may be connected, respectively.

Referring to FIG. 9, a row decoder area X_dec may be disposed between the first cell area CELL AREA1 and the second cell area CELL AREA2. The row decoder area X_dec may be an area in which a decoder, such as a row decoder, is formed. Accordingly, the first cell area CELL AREA1 and the second cell area CELL AREA2 may share the row decoder area X_dec. As an embodiment, the first cell area CELL AREA1 may be a first memory block, and the second cell area CELL AREA2 may be a second memory block. The first memory block and the second memory block may be electrically connected through the first connection pad CPD1 and/or the second connection pad CPD2 and may share the row decoder.

Referring to FIGS. 8 and 9, at least one of the first connection pad CPD1 and the second connection pad CPD2 may be disposed between the first cell area CELL AREA1 and the second cell area CELL AREA2. The first connection pad CPD1 may provide a current path CP between the first cell area CELL AREA1 and the second cell area CELL AREA2. The first connection pad CPD1 may be connected to the first gate line GL1 through the first pad PD1 and may be connected to the second gate line GL2 through the second pad PD2. Accordingly, the first gate line GL1 and the second gate line GL2 may be electrically connected through the first connection pad CPD1. Furthermore, the second connection pad GPD2 may be connected to the first gate line GL1 through the first pad PD1 and may be connected to the second gate line GL2 through the second pad PD2. Accordingly, the first gate line GL1 and the second gate line GL2 may be electrically connected through the second connection pad CPD2.

The row decoder area X_dec may overlap with at least one of the support 20 and the contact areas CT AREA1 and CT AREA2 in the third direction III. As an embodiment, the row decoder may be formed in the same chip as the cell areas CELL AREA1 and CELL AREA2 and may be disposed under or above the support. In such a case, the connection pads CPD1 and CPD2 and the row decoder may be connected through an interconnection structure that penetrates the support 20. As an embodiment, the cell areas CELL AREA1 and CELL AREA2 may be included in a cell chip. The row decoder may be included in a peripheral circuit chip. The semiconductor device may have a structure in which the cell chip and the peripheral circuit chip have been bonded.

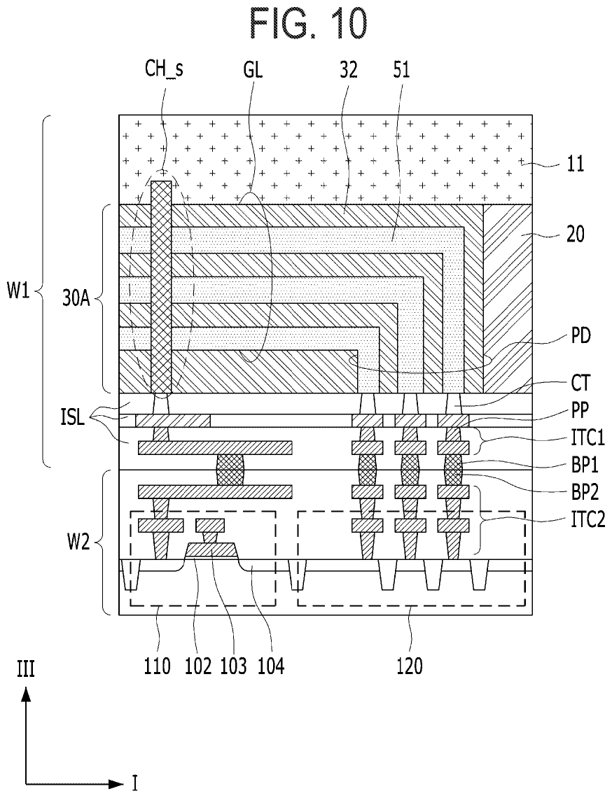

FIG. 10 is a diagram for describing a wafer bonding structure to which a semiconductor device according to an embodiment of the present disclosure has been applied.

Referring to FIG. 10, the first wafer W1 may include a cell array and may be a cell chip. The first wafer W1 may include a source structure 11, the support 20, the conductive layers 51, the insulating layers 32, a contact CT, or a channel structure CH_s or may include the source structure 11, the support 20, the conductive layers 51, the insulating layers 32, the contact CT, or the channel structure CH_s in combination. The source structure 11 may be an impurity area that is formed within a substrate or may be a conductive layer that is separately formed on the substrate. The channel structure CH_s may penetrate the conductive layers 51 and may extend in the third direction III. The channel structure CH_s may include a memory layer and a channel layer. The conductive layers 51 that extend in the first direction I may be gate lines GL. The conductive layers 51 that are connected to the gate lines GL and that extend along the sidewall of the support 20 may be pads PD.

The first wafer W1 may include at least one insulating layer ISL. A pad pattern PP, a first interconnection ITC1, and a first bonding pad BP1 may be formed within at least one of the insulating layers ISL.

A second wafer W2 may include a peripheral circuit. The peripheral circuit may include at least one of a first circuit 110 and a second circuit 120. As an embodiment, the first circuit 110 may be a page buffer, and the second circuit 120 may be a decoder. The first circuit 110 and the second circuit 120 may include at least one transistor. The transistor may include a gate insulating layer 102, a gate electrode 103, and an impurity area 104.

The second wafer W2 may further include a second interconnection ITC2 and a second bonding pad BP2 that are electrically connected to a peripheral circuit structure.

The first bonding pad BP1 and the second bonding pad BP2 may electrically connect the first wafer W1 with the second wafer W2 by being electrically connected.

As described above, the semiconductor device may have a bonding structure in which a plurality of wafers has been bonded. By applying the pad PD and the connection pad CPD to the bonding structure, the area of a decoder can be reduced and the degree of integration of semiconductor devices can be increased.

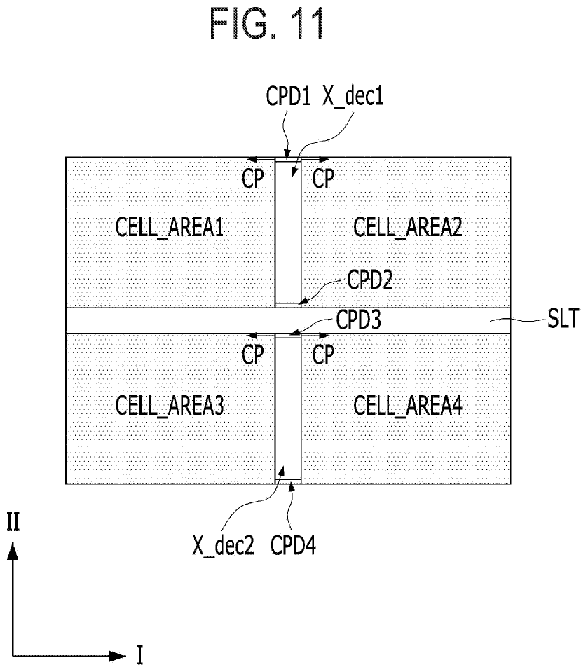

FIG. 11 is a diagram for describing a semiconductor device according to another embodiment of the present disclosure.

Referring to FIG. 11, the semiconductor device may include a first cell area CELL AREA1, a second cell area CELL AREA2, a third cell area CELL AREA3, and a fourth cell area CELL AREA4. The first cell area CELL AREA1 and the second cell area CELL AREA2 may be adjacent to each other in a first direction I. The third cell area CELL AREA3 and the fourth cell area CELL AREA4 may be adjacent to each other in the first direction I. The first cell area CELL AREA1 and the third cell area CELL AREA3 may be adjacent to each other in a second direction II. The second cell area CELL AREA2 and the fourth cell area CELL AREA4 may be adjacent to each other in the second direction II.

A first row decoder X_dec1 may be disposed between the first cell area CELL AREA1 and the second cell area CELL AREA2. A second row decoder X_dec2 may be disposed between the third cell area CELL AREA3 and the fourth cell area CELL AREA4.

A slit structure SLT may be disposed between the first cell area CELL AREA1 and the third cell area CELL AREA3 and between the second cell area CELL AREA2 and the fourth cell area CELL AREA4. The slit structure SLT may extend in the first direction I.

At least one of a first connection pad CPD1 and a second connection pad CPD2 may be disposed between the first cell area CELL AREA1 and the second cell area CELL AREA2. The first cell area CELL AREA1 and the second cell area CELL AREA2 may be electrically connected by the first connection pad CDP1 and/or the second connection pad CPD2. Accordingly, a current path CP that electrically connects the first cell area CELL AREA1 with the second cell area CELL AREA2 through the first connection pad CPD1 and/or the second connection pad CPD2 may be formed.

At least one of a third connection pad CPD3 and a fourth connection pad CPD4 may be disposed between the third cell area CELL AREA3 and the fourth cell area CELL AREA4. The third cell area CELL AREA3 and the fourth cell area CELL AREA4 may be electrically connected by the third connection pad CPD3 and/or the fourth connection pad CPD4. Accordingly, a current path CP that electrically connects the third cell area CELL AREA3 with the fourth cell area CELL AREA4 through the third connection pad CPD3 and/or the fourth connection pad CPD4 may be formed.

A method of manufacturing the semiconductor device according to the aforementioned structure may be performed similarly to the method of manufacturing the semiconductor device, which has been described with reference to FIGS. 1A to 10.

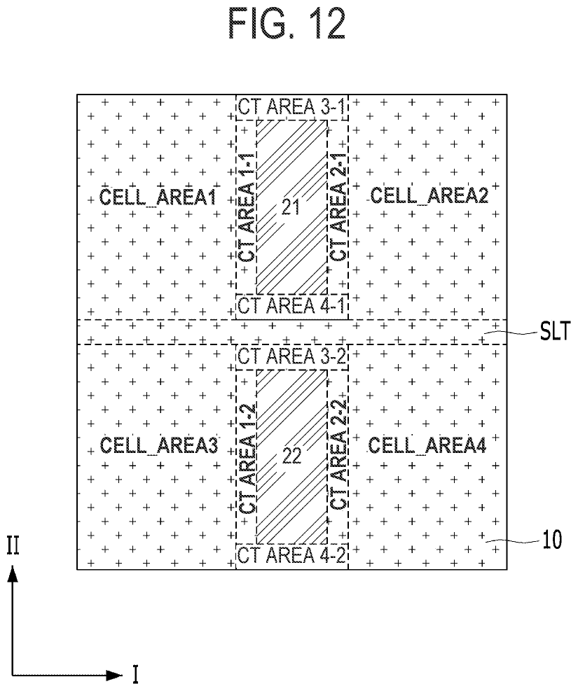

FIGS. 12 to 16C are diagrams for describing a method of manufacturing a semiconductor device according to another embodiment of the present disclosure.

Referring to FIG. 12, a first support 21 and a second support 22 may be formed. As an embodiment, the first and second supports 21 and 22 may be formed on a substrate 10 in a way to extend in a second direction II. For example, each of the first and second supports 21 and 22 may be formed in a hexahedral form by forming a material layer over the substrate 10 and etching the material layer. Alternatively, each of the first and second supports 21 and 22 may be formed by patterning the substrate 10. The material layer may include silicon or polysilicon.

The substrate 10 may include a first cell area CELL AREA1 and a second cell area CELL AREA2 that are adjacent to each other in a first direction I. The first support 21 may be disposed on the substrate 10 between the first cell area CELL AREA1 and the second cell area CELL AREA2. In this case, the first cell area CELL AREA1 may be a location at which the first memory block will be formed, and the second cell gate area CELL AREA2 may be a location at which the second memory block will be formed. In a subsequent process, first gate lines may be stacked in the first cell area CELL AREA1, and second gate lines may be stacked in the second cell area CELL AREA2.

A first contact area CT AREA 1-1 may be disposed between the first cell area CELL AREA1 and the first support 21. In a subsequent process, first pads PD1 may be formed in the first contact area CT AREA 1-1. The first pads PD1 may extend from the first gate lines and may protrude upward along the sidewall of the first support 21. First contacts may be connected to the first pads, respectively.

A second contact area CT AREA 2-1 may be disposed between the second cell area CELL AREA2 and the first support 21. In a subsequent process, second pads PD2 may be formed in the second contact area CT AREA 2-1. The second pads may extend from the second gate lines and may protrude upward along the sidewall of the first support 21. Second contacts may be connected to the second pads, respectively.

A third contact area CT AREA 3-1 may be disposed between the first cell area CELL AREA1 and the second cell area CELL AREA2 and may extend along the sidewall of the first support 21. In a subsequent process, first connection pads that electrically connect the first pads and third pads may be formed in the third contact area CT AREA 3-1. Third contacts may be connected to the first connection pads, respectively.

A fourth contact area CT AREA 4-1 may be disposed between the first cell area CELL AREA1 and the second cell area CELL AREA2 and may extend along the sidewall of the first support 21. In a subsequent process, second connection pads that electrically connect the first pads and the third pads may be formed in the fourth contact area CT AREA 4-1. Fourth contacts may be connected to the second connection pads, respectively.

A first connection area may include the first connection pads. A second connection area may include the second connection pads. The first connection area and the second connection area may be adjacent to in a third direction III. The first support 21, the first contact area CT AREA 1-1, and the second contact area CT AREA 2-1 may be disposed between the first connection area and the second connection area.

The substrate 10 may include a third cell area CELL AREA3 and a fourth cell area CELL AREA4 that are adjacent to each other in the first direction I. The second support 22 may be formed on the substrate 10 between the third cell area CELL AREA3 and the fourth cell area CELL AREA4. In this case, the third cell area CELL AREA3 may be a location at which a third memory block will be formed. The fourth cell area CELL AREA4 may be a location at which a fourth memory block will be formed. In a subsequent process, third gate lines may be stacked in the third cell area CELL AREA3, and fourth gate lines may be stacked in the fourth cell area CELL AREA4.

A fifth contact area CT AREA 1-2 may be disposed between the third cell area CELL AREA3 and the second support 22 and may extend along the sidewall of the second support 22. In a subsequent process, the third pads may be formed in the fifth contact area CT AREA 1-2. The third pads may extend from the third gate lines and may protrude upward along the sidewall of the second support 22. Fifth contacts may be connected to the third pads, respectively.

A sixth contact area CT AREA 2-2 may be disposed between the fourth cell area CELL AREA4 and the second support 22, and may extend along the sidewall of the second support 22. In a subsequent process, fourth pads may be formed in the sixth contact area CT AREA 2-2. The fourth pads may extend from the fourth gate lines and may protrude upward along the sidewall of the second support 22. Sixth contacts may be connected to the fourth pads, respectively.

A seventh contact area CT AREA 3-2 may be disposed between the third cell area CELL AREA3 and the fourth cell area CELL AREA4 and may extend along the sidewall of the second support 22. In a subsequent process, third connection pads that electrically connect the third pads and the fourth pads may be formed in the seventh contact area CT AREA 3-2. Seventh contacts may be connected to the third connection pads, respectively.

An eighth contact area CT AREA 4-2 may be disposed between the third cell area CELL AREA3 and the fourth cell area CELL AREA4 and may extend along the sidewall of the second support 22. In a subsequent process, fourth connection pads that electrically connect the third pads and the fourth pads may be formed in the eighth contact area CT AREA 4-2. Eighth contacts may be connected to the fourth connection pads, respectively.

A third connection area may include the third connection pads. A fourth connection area may include the fourth connection pads. The third connection area and the fourth connection area may be adjacent to each other in the third direction III. The second support 22, the fifth contact area CT AREA 1-2, and the sixth contact area CT AREA 2-2 may be disposed between the third connection area and the fourth connection area.

The first to fourth gate lines, the first to fourth pads, the first to fourth connection pads, and the first to eighth contacts will be described in detail later.

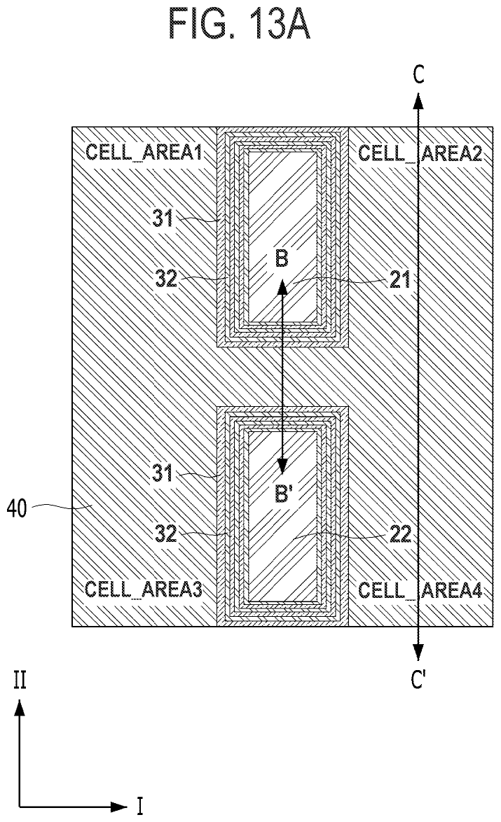

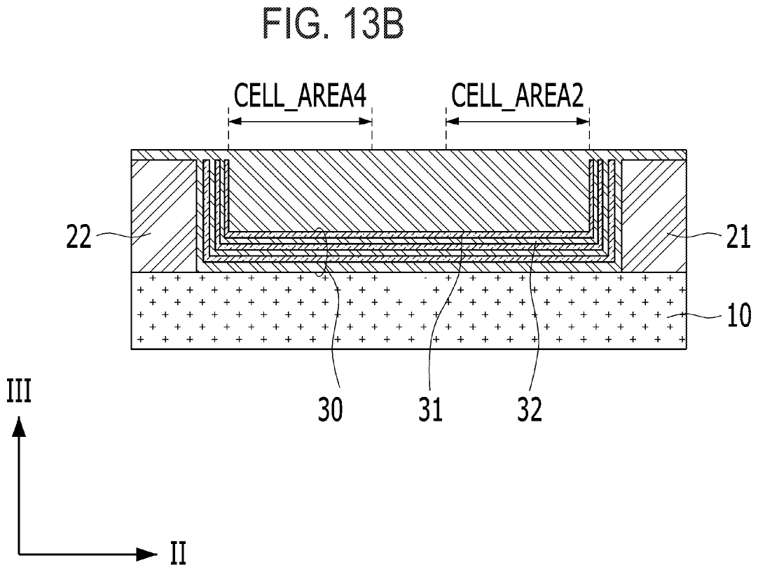

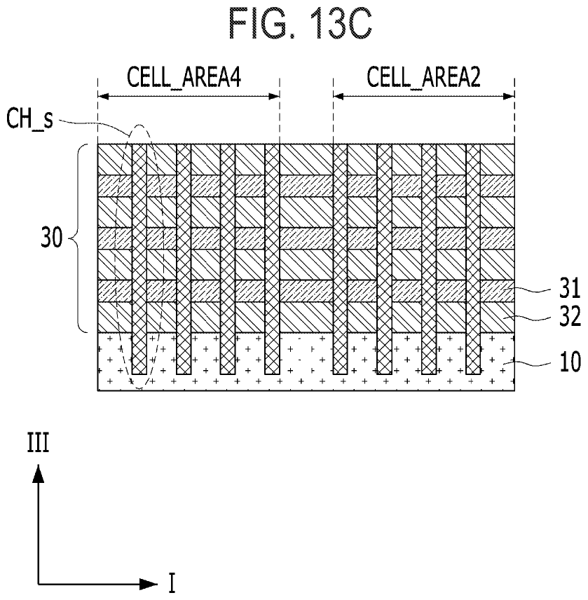

Referring to FIGS. 13A to 13C, a stack 30 may be formed. Furthermore, an insulating layer 40 may be formed over the stack 30. The stack 30 may be formed by alternately stacking first material layers 31 and second material layers 32 over the substrate 10 and along a profile of the first and second supports 21 and 22. The stack 30 may 30 may be formed along the upper surface of the substrate 10, four sidewalls of each of the first and second supports 21 and 22, and the upper surface of each of the first and second supports 21 and 22. The first material layers 31 may be for forming gate lines, such as a word line, a selection line, and a bit line. The second material layers 32 may be for mutually insulating stacked gate lines. For example, the first material layers 31 may include a sacrificial material, such as a nitride. The second material layers 32 may include an insulating material, such as an oxide. As another example, the first material layers 31 may 31 may include a conductive material, such as polysilicon, tungsten, or molybdenum. The second material layers 32 may include an insulating material, such as an oxide.

The stack 30 may be patterned so that each of the first material layers 31 includes a first line part LU1 (shown in FIG. 3A) that is disposed in the first cell area CELL AREA1, a first pad part PU1 that extends from the first line part LU1 and that protrudes upward along the sidewall of the first support 21, a second line part LU2 (shown in FIG. 3A) that is disposed in the second cell area CELL AREA2, a second pad part PU2 that extends from the second line part LU2 and that protrudes upward along the sidewall of the first support 21, and a first connection part CU1 that extends in the first direction I along the sidewall of the first support 21 and that connects the first pad part PU1 with the second pad part PU2. Furthermore, when the stack 30 is patterned, a second connection part CU2 that extends in the first direction I along the sidewall of the first support 21 and that connects the first pad part PU1 with the second pad part PU2 may be additionally formed. The description of the first to fourth line parts LU1, LU2, LU3, and LU4 has been omitted due to the description of the line parts LU1 and LU2 in FIG.3A.

Furthermore, the stack 30 may be patterned so that each of the first material layer 31 includes a third line part LU3 that is disposed in the third cell area CELL AREA3, a third pad part PU3 that extends from the third line part LU3 and that protrudes upward along the sidewall of the second support 22, a fourth line part LU4 that is disposed in the fourth cell area CELL AREA4, a fourth pad part PU3 that extends from the fourth line part LU4 and that protrudes upward along the sidewall of the second support 22, and a third connection part CU3 that extends in the first direction I along the sidewall of the second support 22 and that connects the third pad part PU3 with the fourth pad part PU4. Furthermore, when the stack 30 is patterned, a fourth connection part CU4 that extends in the first direction I along the sidewall of the second support 22 and that connects the third pad part PU3 with the fourth pad part PU4 may be additionally formed.

FIG. 13B may be a cross-sectional view taken along line B-B′ in FIG. 13A. FIG. 13B may be a cross-sectional view that includes cross sections of the first and second supports 21 and 22. Furthermore, FIG. 13C may be a cross-sectional view taken along line C-C′ in FIG. 13A. FIG. 13C may be a cross-sectional view illustrating cross sections of the second cell area CELL AREA2 and the fourth cell area CELL AREA4 illustrated in FIG. 12. FIG. 13C may be a drawing in which a channel structure CH_s has been formed within the stack 30. The channel structure CH_s may include a memory layer and a channel layer. Referring to FIG. 13C, each of the second and fourth cell areas CELL AREA2 and CELL AREA4 may include a plurality of channel structures CH_s. The substrate 10 may include a source structure. The source structure may be an impurity area that is formed within the substrate or may be a conductive layer that is separately formed on the substrate. FIG. 13C illustrates a construction of cross sections of the second and fourth cell areas CELL AREA2 and CELL AREA4, but the first and third cell areas CELL AREA1 and CELL AREA3 may also be constructed to have the same cross sections as the second and fourth cell areas CELL AREA2 and CELL AREA4 in FIG. 13C.

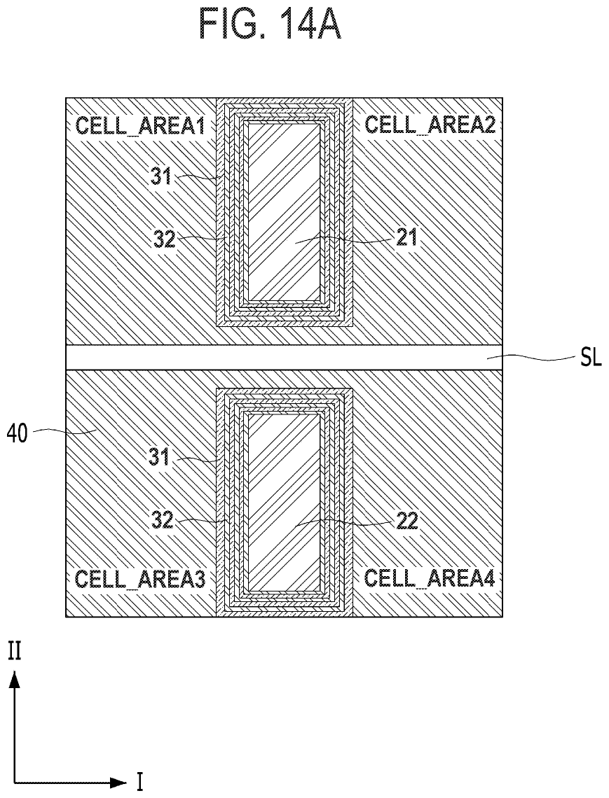

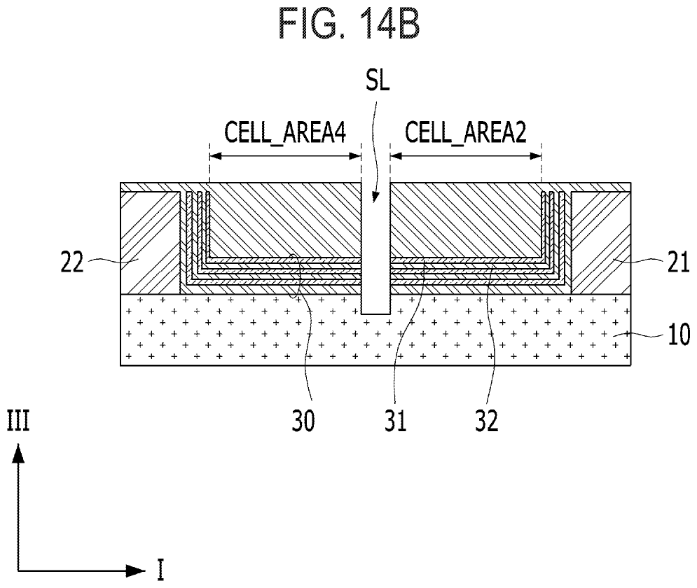

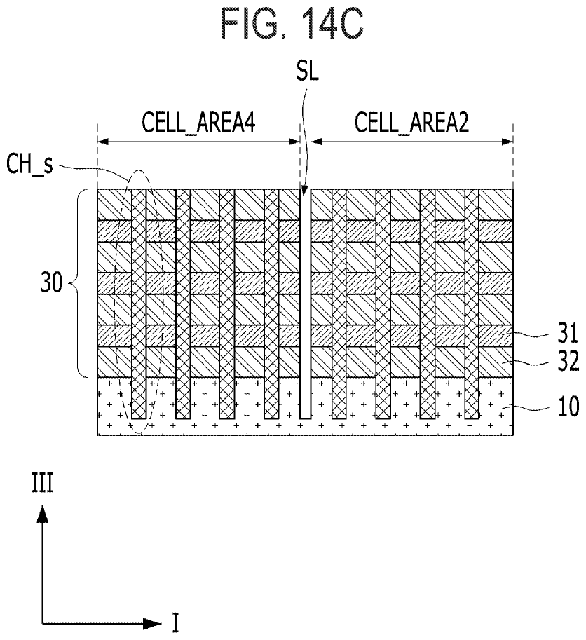

Referring to FIGS. 14A to 14C, a slit SL may be formed in an area between the first and second supports 21 and 22. The slit SL may be disposed between the first and third cell areas CELL AREA1 and CELL AREA3 and between the second and fourth cell areas CELL AREA2 and CELL AREA4. The slit SL may extend in a first direction I on a plane that is defined in the first direction I and a second direction II. The slit SL may extend in a third direction III on a plane that is defined in the first direction I and the third direction III.

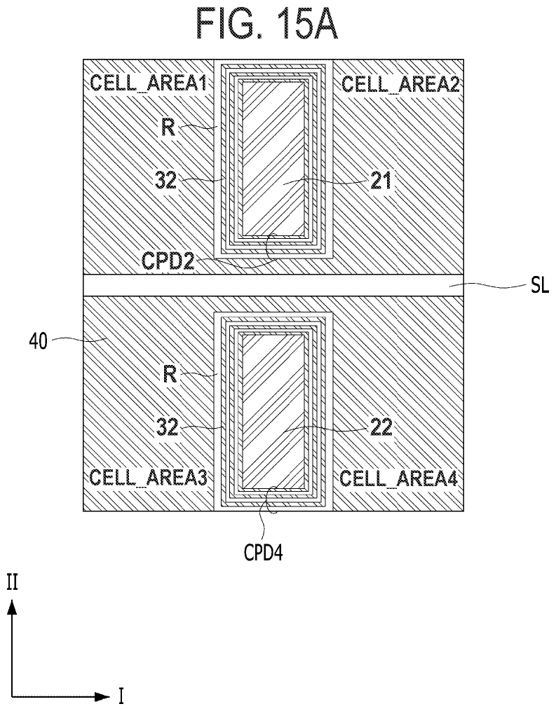

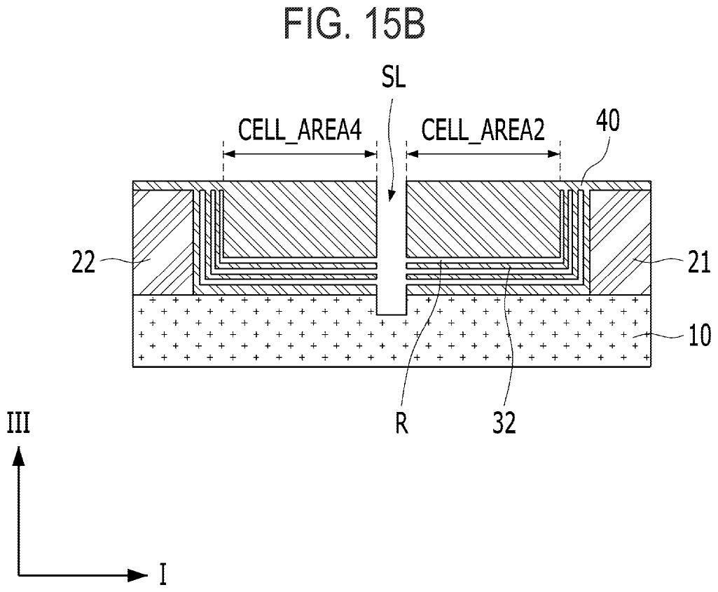

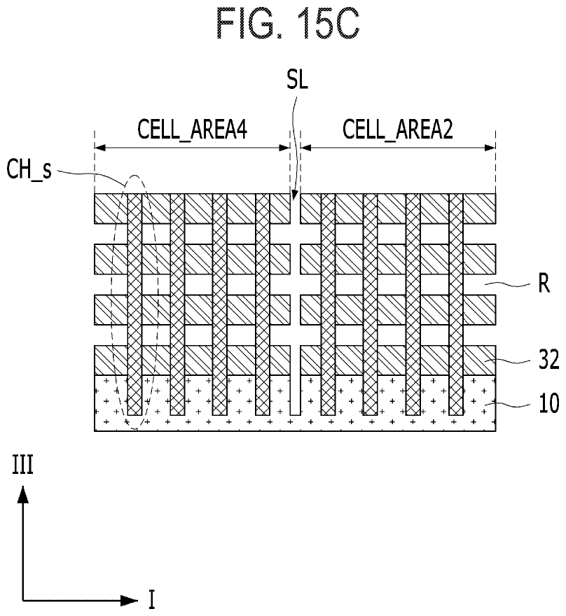

Referring to FIGS. 15A to 15C, a recess area R may be formed in order to form a gate structure. The recess area R may be formed by selectively etching the first material layer 31 through the slit SL.

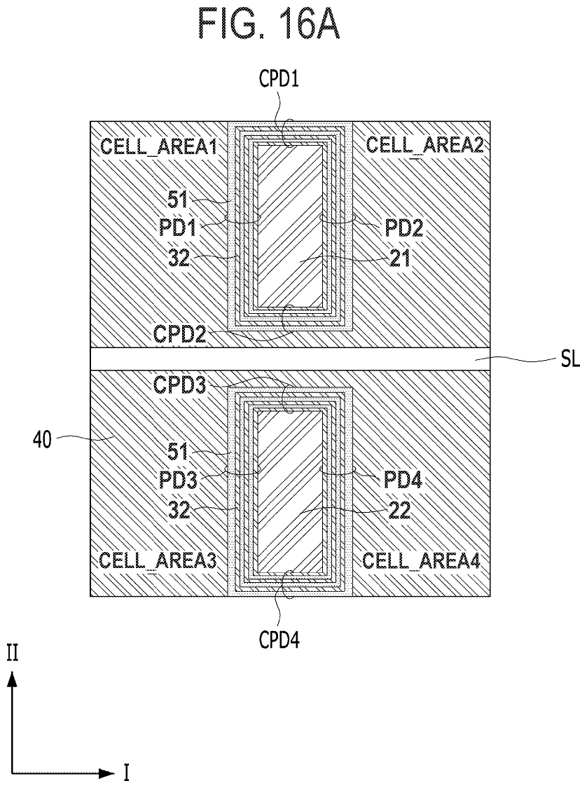

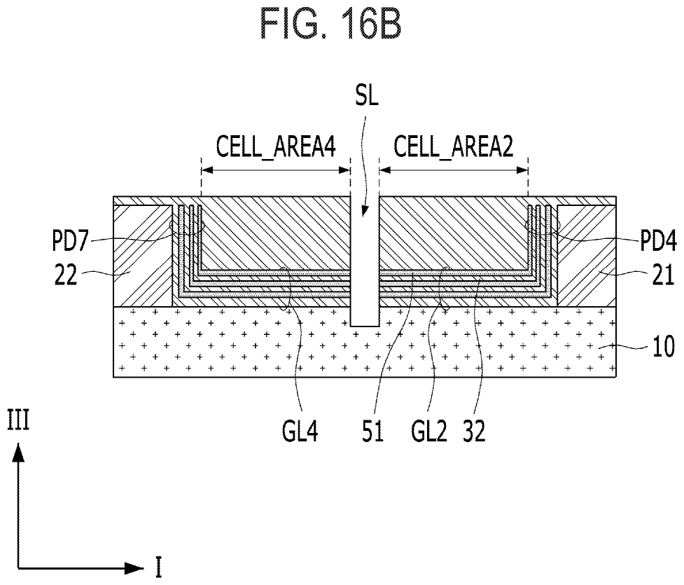

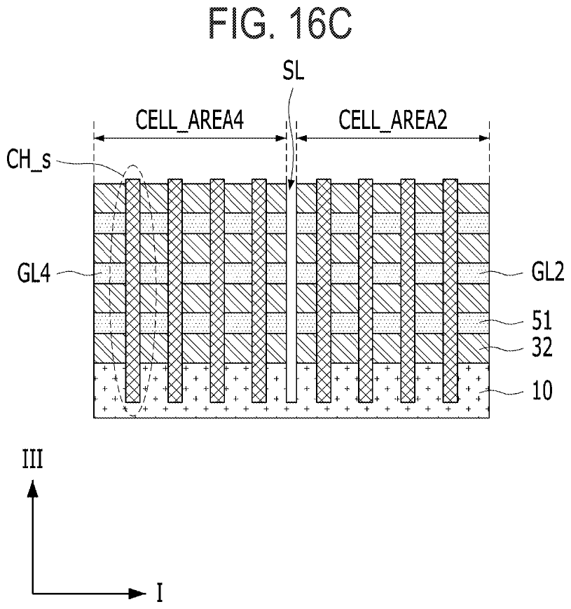

Referring to FIGS. 16A to 16C, conductive layers 51 may be formed. A conductive material may be formed in the recess area R. The conductive material may include a metal material, such as tungsten (W) or molybdenum (MO). Accordingly, first to fourth pads PD1, PD2, PD3, and PD4 and first to fourth connection pads CPD1 and CPD2, CPD3, and CPD4 may be formed.

The first pads PD1 may be disposed between the first cell area CELL AREA1 and the first support 21. The first pads PD1 may extend from first gate lines GL1 of the first cell area CELL AREA1 and may protrude upward along the sidewall of the first support 21.

The second pads PD2 may be disposed between the second cell area CELL AREA2 and the first support 21. The second pads PD2 may extend from second gate lines GL2 of the second cell area CELL AREA2 and may protrude upward along the sidewall of the first support 21.

The third pads PD3 may be disposed between the third cell area CELL AREA3 and the second support 22. The third pads PD3 may extend from third gate lines GL3 of the third cell area CELL AREA3 and may protrude upward along the sidewall of the second support 22.

The fourth pads PD4 may be disposed between the fourth cell area CELL AREA4 and the second support 22. The fourth pads PD4 may extend from fourth gate lines GL4 of the fourth cell area CELL AREA4 and may protrude upward along the sidewall of the second support 22.

The first connection pads CPD1 may be disposed between the first cell area CELL AREA1 and the second cell area CELL AREA2, may extend along the sidewall of the first support 21, and may electrically connect the first pads PD1 with the second pads PD2.

The second connection pads CPD2 may be disposed between the first cell area CELL AREA1 and the second cell area CELL AREA2, may extend along the sidewall of the first support 21, and may electrically connect the first pads PD1 with the second pads PD2. Accordingly, the first and second connection pads CPD1 and CPD2 may electrically connect the first cell area CELL AREA1 with the second cell area CELL AREA2. For example, the first and second connection pads CPD1 and CPD2 may electrically connect the first gate lines GL1 of the first cell area CELL AREA1 with the second gate lines GL2 of the second cell area CELL AREA2.

The third connection pads CPD3 may be disposed between the third cell area CELL AREA3 and the fourth cell area CELL AREA4, may extend along the sidewall of the second support 22, and may electrically connect the third pads PD3 with the fourth pads PD4.

The fourth connection pads CPD4 may be disposed between the third cell area CELL AREA3 and the fourth cell area CELL AREA4, may extend along the sidewall of the second support 22, and may electrically connect the third pads PD3 with the fourth pads PD4. Accordingly, the third and fourth connection pads CPD3 and CPD4 may electrically connect the third cell area CELL AREA3 with the fourth cell area CELL AREA4. For example, the third and fourth connection pads CPD3 and CPD4 may electrically connect the third gate lines GL3 of the third cell area CELL AREA3 with the fourth gate lines GL4 of the fourth cell area CELL AREA4.

Contacts may be formed over the first to fourth pads PD1 to PD4 and the first to fourth connection pads CPD1 to CPD4 by using the same manufacturing method as that used in FIGS. 6A to 7B.

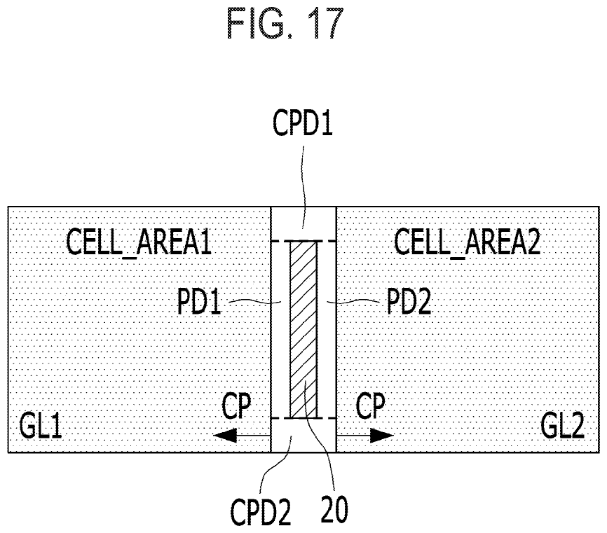

FIGS. 17 to 20 are diagrams for describing a semiconductor device according to various embodiments of the present disclosure.

FIG. 17 may illustrate a case in which the length of the support 20 in the second direction II is shorter than the length of the first and second cell areas CELL AREA1 and CELL AREA2 in the second direction II. The support 20 may be disposed between the first cell area CELL AREA1 and the second cell area CELL AREA2. The first pad PD1 may extend from the first gate line GL1 of the first cell area CELL AREA1 and may protrude upward along the sidewall of the support 20. The second pad PD2 may extend from the second gate line GL2 of the second cell area CELL AREA2 and may protrude upward along the sidewall of the support 20. The first connection pad CPD1 may be disposed between the first cell area CELL AREA1 and the second cell area CELL AREA2 and may extend in the first direction I along the sidewall of the support 20. The first connection pad CPD1 may electrically connect the first cell area CELL AREA1 with the second cell area CELL AREA2. As an embodiment, the first connection pad CPD1 may electrically connect the first gate line GL1 of the first cell area CELL AREA1 with the second gate line GL2 of the second cell area CELL AREA2. The second connection pad CPD2 may be disposed between the first cell area CELL AREA1 and the second cell area CELL AREA2 and may extend in the first direction I along the sidewall of the support 20. The second connection pad CPD1 may electrically connect the first cell area CELL AREA1 with the second cell area CELL AREA2. As an embodiment, the second connection pad CPD2 may electrically connect the first gate line GL1 of the first cell area CELL AREA1 with the second gate line GL2 of the second cell area CELL AREA2. The second connection pad CPD2 may be disposed between the support 20 and the slit structure SLT.

As described above, the semiconductor device may use two connection pads that are formed on both sidewalls of the support 20 that extend in the first direction I as a current path CP, electrically connecting two adjacent cell areas CELL AREA1 with CELL AREA2.

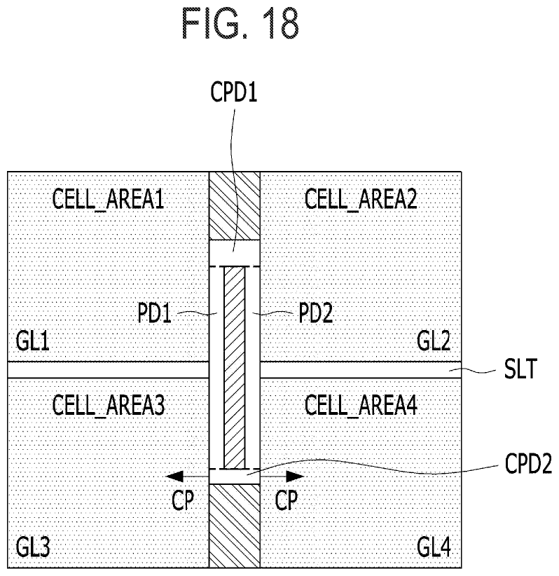

FIG. 18 may illustrate a case in which the length of the support 20 in the second direction II is longer than the length of each of the cell areas CELL AREA1, CELL AREA2, CELL AREA3, and CELL AREA4 in the second direction II. The support 20 may be disposed between the third cell area CELL AREA3 and the fourth cell area CELL AREA4 and may extend between the first cell area CELL AREA1 and the second cell area CELL AREA2. The first pad PD1 may be disposed between the third cell area CELL AREA3 and the support 20 and may extend into the first cell area CELL AREA1 along the sidewall of the support 20. The second pad PD2 may be disposed between the fourth cell area CELL AREA4 and the support 20 and may extend in the second cell area CELL AREA2. The first pad PD1 may extend from the first gate line GL1 of the first cell area CELL AREA1, protrude upward along the sidewall of the support 20, extend from the third gate line GL3 of the third cell area CELL AREA3, and protrude along the sidewall of the support 20. The second pad PD2 may extend from the second gate line GL2 of the second cell area CELL AREA2, protrude upward along the sidewall of the support 20, extend from the fourth gate line GL4 of the fourth cell area CELL AREA4, and protrude along the sidewall of the support 20. The first connection pad CPD1 may be disposed between the first cell area CELL AREA1 and the second cell area CELL AREA2 and may extend in the first direction I along the sidewall of the support 20. The first connection pad CPD1 may electrically connect the first cell area CELL AREA1 with the second cell area CELL AREA2. As an embodiment, the first connection pad CPD1 may electrically connect the first gate line GL1 of the first cell area CELL AREA1 with the second gate line GL2 of the second cell area CELL AREA2. The second connection pad CPD2 may be disposed between the third cell area CELL AREA3 and the fourth cell area CELL AREA4 and may extend in the first direction I along the sidewall of the support 20. The second connection pad CPD2 may electrically connect the third cell area CELL AREA3 with the fourth cell area CELL AREA4. As an embodiment, the second connection pad CPD2 may electrically connect the third gate line GL3 of the third cell area CELL AREA3 with the fourth gate line GL4 of the fourth cell area CELL AREA4.

As described above, the semiconductor device may use a connection pad that is formed on each of both sidewalls of the support 20 that extends in the first direction I as a current path CP that electrically connects two adjacent cell areas CELL AREA1 with CELL AREA2 and CELL AREA3 with CELL AREA4.

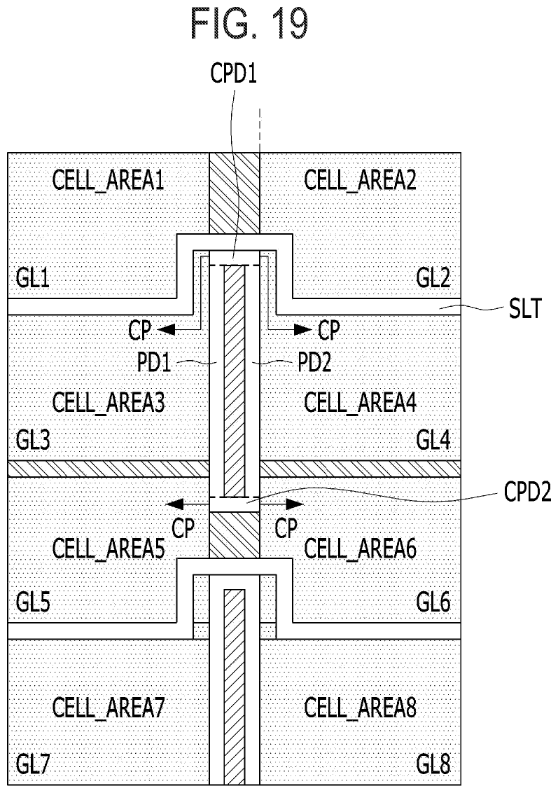

FIG. 19 may illustrate a case in which the length of the support 20 in the second direction II is longer than the length of each of the cell areas CELL AREA1, CELL AREA2, CELL AREA3, CELL AREA4, CELL AREA5, and CELL AREA6 in the second direction II. The support 20 may be disposed between the third cell area CELL AREA3 and the fourth cell area CELL AREA4 and may extend between the third cell area CELL AREA3 and the fourth cell area CELL AREA4. Furthermore, the support 20 mayprotrude between the first cell area CELL AREA1 and the second cell area CELL AREA2 and may protrude between the fifth cell area CELL AREA5 and the sixth cell area CELL AREA6. The slit structure SLT may be connected in the first direction I and may include a curve that is bent along the end of the support 20 in some areas of the slit structure. The first pad PD1 may extend from the third gate line GL3 of the third cell area CELL AREA3 and may protrude upward along the sidewall of the support 20. Furthermore, the first pad PD1 may extend from the fourth gate line GL4 of the fourth cell area CELL AREA4 and may protrude upward along the sidewall of the support 20. The second pad PD2 may extend from the fourth gate line GL4 of the fourth cell area CELL AREA4 and may protrude upward along the sidewall of the support 30. Furthermore, the second pad PD2 may extend from the sixth gate line GL6 of the sixth cell area CELL AREA6 and may protrude upward along the sidewall of the support 20. The first connection pad CPD1 may be disposed between the first cell area CELL AREA1 and the second cell area CELL AREA2 and may extend in the first direction I along the sidewall of the support 20. The first connection pad CPD1 may electrically connect the third cell area CELL AREA3 with the fourth cell area CELL AREA4. As an embodiment, the first connection pad CPD1 may electrically connect the third gate line GL3 of the third cell area CELL AREA3 with the fourth gate line GL4 of the fourth cell area CELL AREA4. The second connection pad CPD2 may electrically connect the fifth cell area CELL AREA5 with the sixth cell area CELL AREA6. As an embodiment, the second connection pad CPD2 may electrically connect the fifth gate line GL5 of the fifth cell area CELL AREA5 with the sixth gate line GL6 of the sixth cell area CELL AREA6.

As described above, the semiconductor device may use each connection pad that is formed on both sidewalls of the support 20 that extends in the first direction I as a current path CP that electrically connects two adjacent cell areas CELL AREA3 with CELL AREA4 or CELL AREA5 with CELL AREA6. In this case, the sidewalls of the support 20 that extend in the first direction I may be formed within the first and second cell areas CELL AREA1 and CELL AREA2. In contrast, the first connection pad CPD1 that is formed on the sidewall of the support 20 that extends in the first direction I may be electrically separated from the first and second cell areas CELL AREA1 and CELL AREA2 by the slit SLT so that the first connection pad CPD1 may function to electrically connect the third and fourth cell areas CELL AREA3 and CELL AREA4.

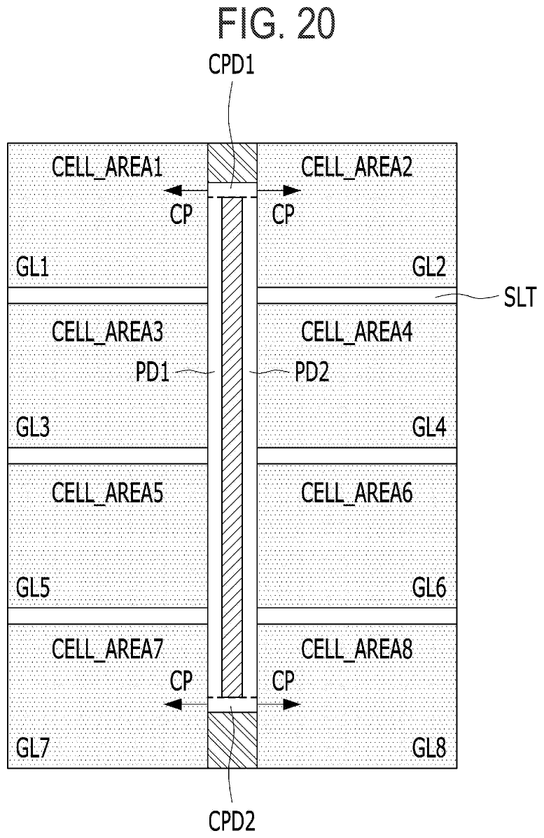

FIG. 20 may illustrate a case in which the length of the support 20 in the second direction II is equal to or greater than twice the length of each of cell areas CELL AREA1, CELL AREA2, CELL AREA3, CELL AREA4, CELL AREA5, CELL AREA6, CELL AREA7, and CELL AREA8 in the second direction II. The support 20 may be disposed between the third cell area CELL AREA3 and the fourth cell area CELL AREA4 and between the fifth cell area CELL AREA5 and the sixth cell area CELL AREA6 and may extend between the third cell area CELL AREA3 and the fourth cell area CELL AREA4 and between the fifth cell area CELL AREA5 and the sixth cell area CELL AREA6. The support 20 mayprotrude between the first cell area CELL AREA1 and the second cell area CELL AREA2 and may protrude between the seventh cell area CELL AREA7 and the eighth cell area CELL AREA8. The slit structure SLT may be disposed between the first cell area CELL AREA1 and the third cell area CELL AREA3, between the second cell area CELL AREA2 and the fourth cell area CELL AREA4, between the third cell area CELL AREA3 and the fifth cell area CELL AREA5, between the fourth cell area CELL AREA4 and the sixth cell area CELL AREA6, between the fifth cell area CELL AREA5 and the seventh cell area CELL AREA7, and between the sixth cell area CELL AREA6 and the eighth cell area CELL AREA8, and the slit structure SLT may extend in the first direction I. The first pad PD1 may extend from gate lines GL1, GL3, GL5, and GL7 of the first cell area CELL AREA1, the third cell area CELL AREA3, the fifth cell area CELL AREA5, and the seventh cell area CELL AREA7, respectively, and the first pad PD1 may protrude upward along the sidewall of the support 20. The second pad PD2 may extend from gate lines GL2, GL4, GL6, and GL8 of the second cell area CELL AREA2, the fourth cell area CELL AREA4, the sixth cell area CELL AREA6, and the eighth cell area CELL AREA8, respectively, and the second pad PD2 may protrude upward along the sidewall of the support 20. The first connection pad CPD1 may be disposed between the first cell area CELL AREA1 and the second cell area CELL AREA2 and may extend in the first direction I. The first connection pad CPD1 may electrically connect the first cell area CELL AREA1 with the second cell area CELL AREA2. As an embodiment, the first connection pad CPD1 may electrically connect the first gate line GL1 of the first cell area CELL AREA1 with the second gate line GL2 of the second cell area CELL AREA2. The second connection pad CPD2 may be disposed between the seventh cell area CELL AREA7 and the eighth cell area CELL AREA8 and may extend in the first direction I. The second connection pad CPD2 may electrically connect the seventh cell area CELL AREA7 with the eighth cell area CELL AREA8. As an embodiment, the second connection pad CPD2 may electrically connect the seventh gate line GL7 of the seventh cell area CELL AREA7 with the eighth gate line GL8 of the eighth cell area CELL AREA8.

As described above, the semiconductor device may use each connection pad that is formed on both sidewalls of the support 20 that extends in the first direction I as a current path CP that electrically connects two adjacent cell areas CELL AREA1 with CELL AREA2 or CELL AREA7 with CELL AREA8.

Although embodiments according to the technical spirit of the present disclosure have been described above with reference to the accompanying drawings, the embodiments have been provided to merely describe embodiments according to the concept of the present disclosure, and the present disclosure is not limited to the embodiments. A person having ordinary knowledge in the art to which the present disclosure pertains may substitute, modify, and change the embodiments in various ways without departing from the technical spirit of the present disclosure written in the claims. Such substitutions, modifications, and changes may be said to belong to the scope of the present disclosure.

What is claimed is:

1. A semiconductor device comprising:
a first cell area and a second cell area adjacent to each other in a first direction;
a support disposed between the first cell area and the second cell area;
first gate lines stacked in the first cell area;
first pads configured to extend from the first gate lines and configured to protrude upward along a first sidewall of the support;
second gate lines stacked in the second cell area;
second pads configured to extend from the second gate lines and configured to protrude upward along a second sidewall of the support; and
first connection pads configured to extend in the first direction along a third sidewall of the support and configured to electrically connect the first pads with the second pads.

2. The semiconductor device of claim 1,
wherein each of the first gate line, the first pad, the second gate line, the second pad, and the first connection pad is comprised of a conductive layer.

3. The semiconductor device of claim 1, further comprising second connection pads configured to extend in the first direction along a fourth sidewall of the support and configured to electrically connect the first pads with the second pads.

4. The semiconductor device of claim 3,
wherein each of the first gate line, the second gate line, the first connection pad, and the second connection pad is comprised of a conductive layer.

5. The semiconductor device of claim 1, further comprising:
first contacts connected to the first pads, respectively; and
second contacts connected to the second pads, respectively.

6. The semiconductor device of claim 1, further comprising third contacts connected to the first connection pads, respectively.

7. The semiconductor device of claim 1, further comprising a third cell area and a fourth cell area adjacent to each other in the first direction,
wherein the third cell area is adjacent to the first cell area in a second direction, the second direction intersecting the first direction, and
wherein the fourth cell area is adjacent to the second cell area in the second direction.

8. The semiconductor device of claim 7, further comprising a slit structure configured to extend in the first direction between the first cell area and the third cell area and between the second cell area and the fourth cell area.

9. The semiconductor device of claim 8, wherein the first connection pads are disposed between the support and the slit structure.

10. The semiconductor device of claim 7, wherein the support extends between the third cell area and the fourth cell area.

11. The semiconductor device of claim 10, further comprising:
third gate lines stacked in the third cell area;
third pads configured to extend from the third gate lines and configured to protrude upward along the sidewall of the support;
fourth gate lines stacked in the fourth cell area;
fourth pads configured to extend from the fourth gate lines and configured to protrude upward along the sidewall of the support; and
second connection pads configured to extend in the first direction along the sidewall of the support and configured to connect the third pads with the fourth pads.

12. The semiconductor device of claim 11,
wherein the third pads extend into the first cell area along the sidewall of the support, and
wherein the fourth pads extend into the second cell area along the sidewall of the support.
